(19) United States
(12) Patent Application Publication
(10) Pub. No.: US 2012/0155053 A1
(43) Pub. Date: Jun. 21, 2012

(54) CASE FOR ELECTRONIC COMPONENTS

(76) Inventor: Yuichiro Nara, Tokyo (JP)

(21) Appl. No.: 13/391,813

(22) PCT Filed: Aug. 26, 2009
(86) PCT No.: PCT/JP2009/064847

§ 371 Date: Feb. 22, 2012

(51) Int. Cl. H05K 5/03

(52) U.S. Cl. 361/816

(57) ABSTRACT

Provided is a case for electronic components in which an openable and closable lid is mounted to a container for housing a plurality of electronic components. The lid includes a shield projecting from its inner surface and located between two electronic components when the lid is closed so that its leading end can abut on a mounting surface on which the two electronic components are mounted.

### BACKGROUND ART

Recent miniaturization of an electronic device has been accompanied by an increase in high density electronic component mounting in the electronic devices. The electronic components are accordingly arranged close to one another in the electronic device.

To assure integrity, the spatial distance and creeping distance must be sufficiently ensured between the electronic components. The spatial distance is the length of the shortest path for connecting two electronic components via a space, and the creeping distance is the length of the shortest path for connecting the two electronic components along the surface of an insulator.

Necessary spatial and creeping distances are different from one combination of two electronic components to another, and reference values of a spatial distance and a creeping distance are determined for each combination.

FIG. 1A is a side sectional view showing an electronic substrate disposed in a general electronic device. In electronic substrate 40, electronic components 421 and 422 are mounted on substrate member 411. Between electronic components 421 and 422, a spatial distance and a creeping distance equal to or more than reference values corresponding to a combination of electronic components 421 and 422 must be ensured.

Patent Literature 1 describes a technology for making longer the spatial distance and creeping distance between electronic components located on an electronic substrate. On the electronic substrate described in Patent Literature 1, the shielding member made of an insulating material is disposed between the two electronic components.

Specifically, according to the technology described in Patent Literature 1, as shown in FIG. 1B, shielding member 50 is disposed between electronic components 421 and 422, and shielding member 50 isolates electronic components 421 and 422 from each other. As a result, the spatial distance and a creeping distance between electronic components 421 and 422 are made longer.

### CITATION LIST

### Patent Literature

Patent Literature 1: JP2002-164503A

### SUMMARY OF INVENTION

### Problem to be Solved by Invention

However, when shielding member 50 shown in FIG. 1B is added to a configuration of electronic substrate 40 shown in FIG. 1A, a step of disposing shielding member 50 must be added to the manufacturing process of electronic substrate 40. Such an increase in the number of manufacturing steps increases manufacturing costs.

It is therefore an object of the present invention to provide a case for electronic components, which can ensure the spatial distance and creeping distance between electronic components without disposing any shielding member as another member in an electronic device.

### Solution to Problem

To achieve the object, the present invention provides a case for electronic components in which an openable and closable lid is mounted to a container for housing a plurality of electronic components. The lid includes a shield projecting from its inner surface and located between two electronic components when the lid is closed so that its leading end can abut on a mounting surface on which the two electronic components are mounted.

### EFFECTS OF INVENTION

According to the present invention, a case for electronic components that can ensure the spatial distance and a creeping distance between electronic components can be provided.

### BRIEF DESCRIPTION OF DRAWINGS

FIG. 1A A side sectional view showing a general electronic substrate.

FIG. 1B A side sectional view showing a general electronic substrate.

FIG. 2A A perspective view showing a case for electronic components according to an embodiment of the present invention.

FIG. 2B A perspective view showing the case for electronic components shown in FIG. 2A.

FIG. 3A A perspective view showing the case for electronic components shown in FIG. 2A.

FIG. 3B A perspective view showing the case for electronic components shown in FIG. 2A.

FIG. 4A A partial sectional view cut along line A-A′ shown in FIG. 2A, showing an electronic substrate housed in the case for electronic components shown in FIG. 2A.

FIG. 4B A partial sectional view cut along line B-B′ shown in FIG. 3A, showing the electronic substrate housed in the case for electronic components shown in FIG. 2A.

FIG. 5A A perspective view showing a container in the case for electronic components shown in FIG. 2A.

FIG. 5B A perspective view showing the container in the case for electronic components shown in FIG. 2A.

FIG. 6A A perspective view showing a lid in the case for electronic components shown in FIG. 2A.

FIG. 6B A perspective view showing the lid in the case for electronic components shown in FIG. 2A.

FIG. 7 A view showing an inner surface of the lid in the case for electronic components shown in FIG. 2A.

FIG. 8 A partial sectional view cut along line C-C′ shown in FIG. 3A, showing the case for electronic components shown in FIG. 2A.

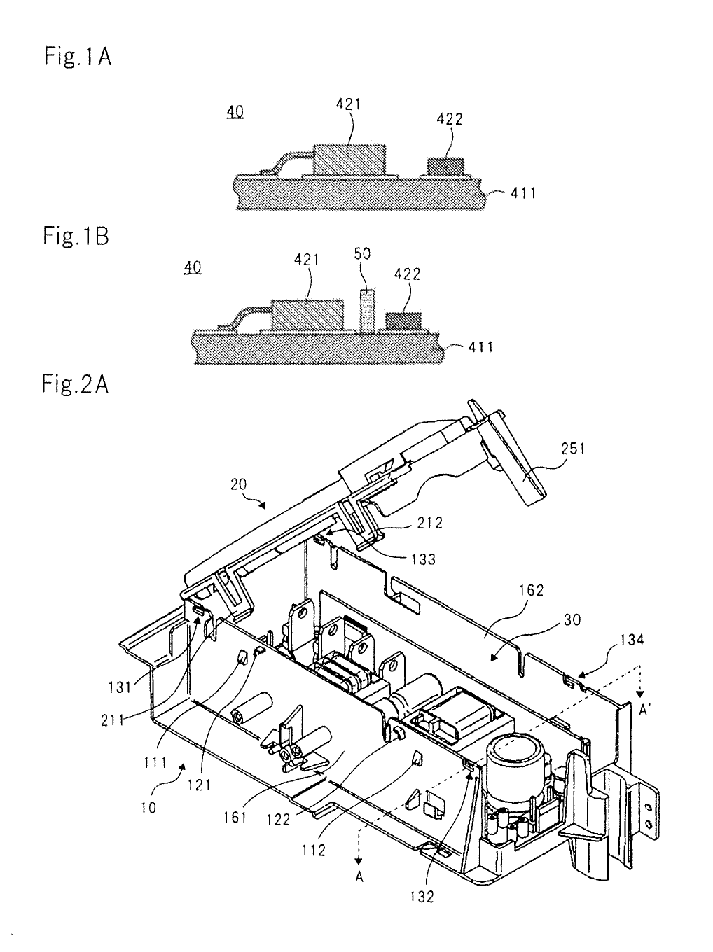

### DESCRIPTION OF EMBODIMENT

Next, an embodiment of the present invention will be described referring to the drawings.

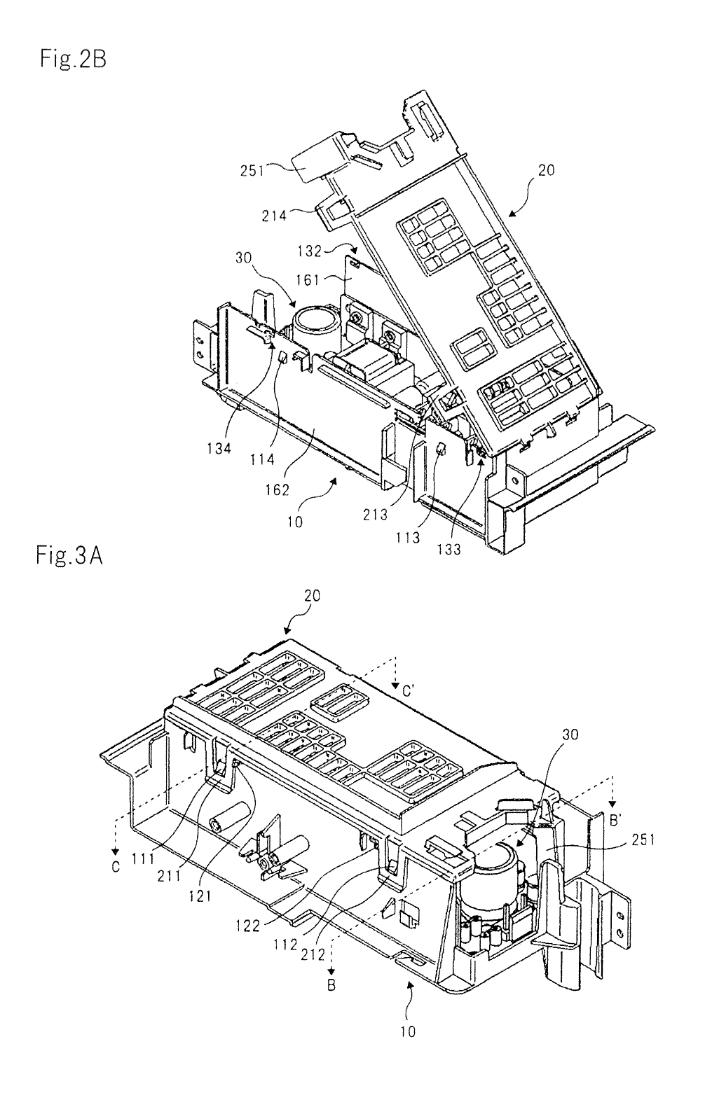

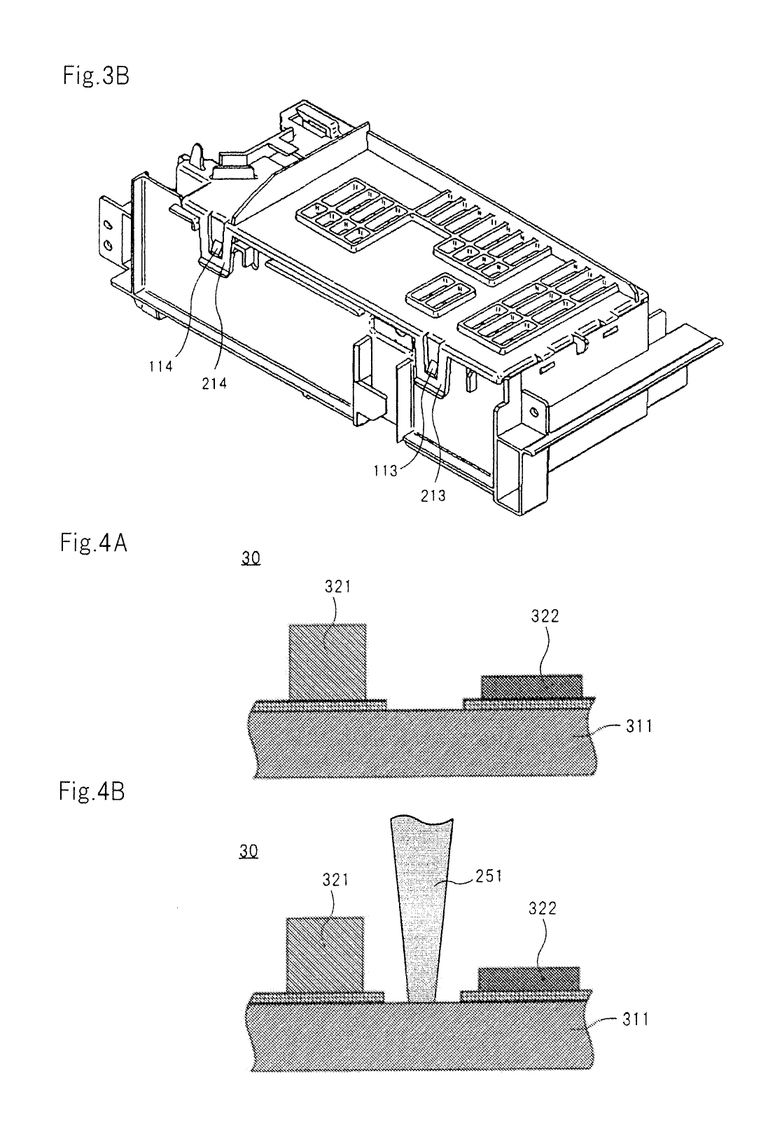

FIGS. 2A and 2B and FIGS. 3A and 3B are perspective views showing a case for electronic components according to an embodiment of the present invention. An end surface of the case for electronic components on a front side in a longitudinal direction shown in FIG. 3A is set as the front surface, and an end surface on a deep side is set as the rear surface. In other words, FIGS. 2A and 3A show the front side, while FIGS. 2B and 3B show the rear side.

The case for electronic components includes container 10 for housing electronic substrate 30, and lid 20 mounted to container 10. Lid 20 is openable and closable. FIGS. 2A and 2B show an opened state of lid 20, while FIGS. 3A and 3B show a closed state of lid 20.

The case for electronic components is included in an electronic device in the closed state of lid 20 shown in FIGS. 3A and 3B.

Lid 20 includes shield 251 that extends downward from an end of the front side. In the opened state of lid 20 shown in FIGS. 2A and 2B, shield 251 is separated from electronic substrate 30. On the other hand, in the closed state of lid 20 shown in FIGS. 3A and 3B, the lower end of shield 251 abuts on the upper surface of electronic substrate 30.

Referring to FIGS. 4A and 4B, shield 251 is described in detail. FIG. 4A is a partial sectional view cut along the line A-A′ shown in FIG. 2A, and FIG. 4B is a partial sectional view cut along the line B-B′ shown in FIG. 3A.

Electronic substrate 30 includes substrate member 311, and electronic components 321 and 322 mounted on a surface of substrate member 311 that is a mounting surface. For the spatial distance and creeping distance between electronic components 321 and 322, reference values necessary for securing integrity are set.

In an opened state of lid 20 shown in FIG. 4A, the spatial distance and the creeping distance between electronic components 321 and 322 on substrate member 311 are less than the reference values. When electronic substrate 30 is actually driven, therefore, the spatial distance and the creeping distance between electronic components 321 and 322 must be set longer.

As described above, the case for electronic components is included in the electronic device in the closed state of lid 20. Thus, lid 20 is always closed during driving of electronic substrate 30.

In a closed state of lid 20, as shown in FIG. 4B, shield 251 of lid 20 is located between electronic components 321 and 322. The leading end of shield 251 abuts on the surface of substrate member 311 that is the mounting surface of electronic components 321 and 322.

Thus, in the state shown in FIG. 4B, as compared with the state shown in FIG. 4A, while there is no change in the relative position of electronic components 321 and 322, the spatial distance and creeping distance between electronic components 321 and 322 are made longer by shield 251 that isolates electronic components 321 and 322 from each other. In this case, the spatial distance and creeping distance between electronic components 321 and 322 on substrate member 311 are equal to or more than the reference values.

Thus, during driving of electronic substrate 30 housed in the case for electronic components according to this embodiment, the spatial distance and creeping distance between electronic components 321 and 322 located on electronic substrate 30 are maintained equal to or more than the reference values.

According to this embodiment, one shield 251 is disposed on the end of the front side of lid 20. However, the arrangement and the number of shields 251 can be determined as occasion demands. In other words, shield 251 can be formed in an arbitrary position on an inner surface of lid 20, and located between the two electronic components in container 10.

Lid 20 is made of a resin material such as plastic having insulation properties. The resin material can be easily formed into various shapes. Shield 251 can accordingly be formed integrally with lid 20.

Thus, shield 251 does not need to be disposed as a member separate from lid 20. Addition of shield 251 does not lead to an increase in the number of manufacturing steps of the case for electronic components. In this embodiment, shield 251 is formed into a wedge shape where the side section becomes gradually thinner in the downward direction.

The two electronic components between which the spatial distance and the creeping distance are made longer by shield 251 are not always located on the electronic substrate. For example, even when electronic components 321 and 322 are directly mounted on container 10, it is only required that shield 251 be located between electronic components 321 and 322 when lid 20 is closed.

Hereinafter, the configuration of the case for electronic components according to this embodiment will be described in detail.

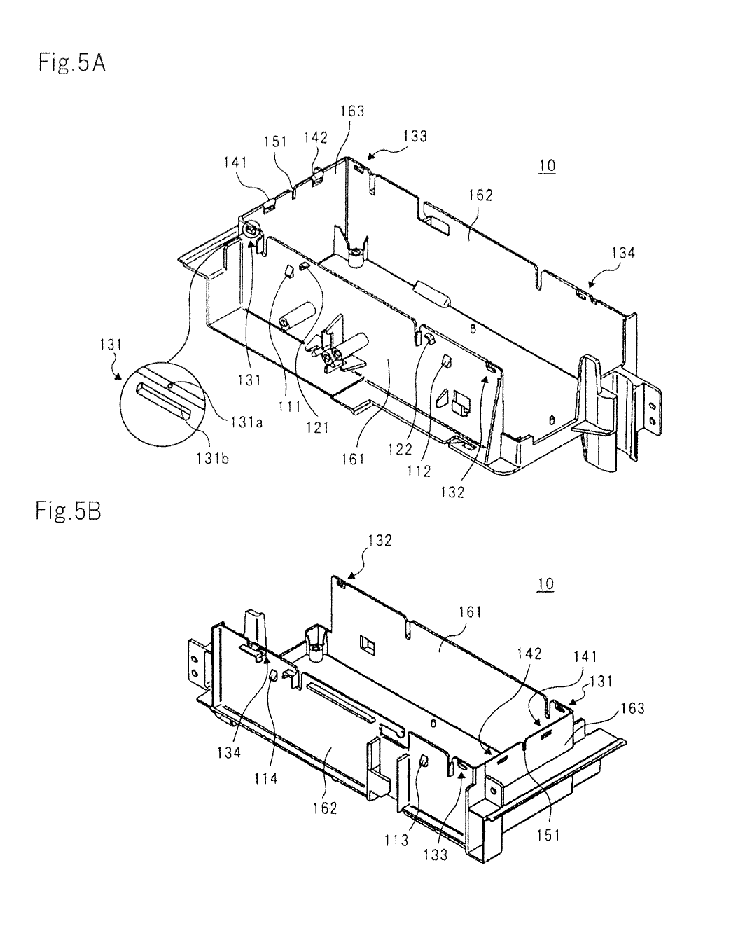

FIGS. 5A and 5B are perspective views showing container 10 of the case for electronic components according to this embodiment. FIG. 5A shows the front side, and FIG. 5B shows the rear side.

Container 10 includes locking parts 111 and 112 projecting from the outer surface of one side wall 161, and locking parts 113 and 114 projecting from the outer surface of other side wall 162. In side wall 161, convex parts 121 and 122 are arranged in positions close to locking parts 111 and 112. Convex parts 121 and 122 also project from the outer surface of side wall 161.

Deformation parts 131 and 132 are located on the upper end of side wall 161, and deformation parts 133 and 134 are located on the upper end of side wall 162. Deformation parts 131 and 133 are arranged on the rear side, while deformation parts 132 and 134 are arranged on the front side.

As shown in the enlarged view of the left lower side shown in FIG. 5A, deformation part 131 includes projection 131a projecting from the upper end. Below projection 131a, slit 131b is formed through side wall 161 of container 10. Deformation parts 132, 133, 134 also include projections and slits formed as in the case of deformation part 131.

Shafts 141 and 142 are arranged on the upper end of rear wall 163 of container 10. Shafts 141 and 142 are formed into semicircular column shapes where center axes are directed sideward. Circumferential surfaces of shafts 141 and 142 project from rear wall 163 to the front side. Between shafts 141 and 142, notch 151, which is cut from the upper end of rear wall 163 in the downward direction, is formed.

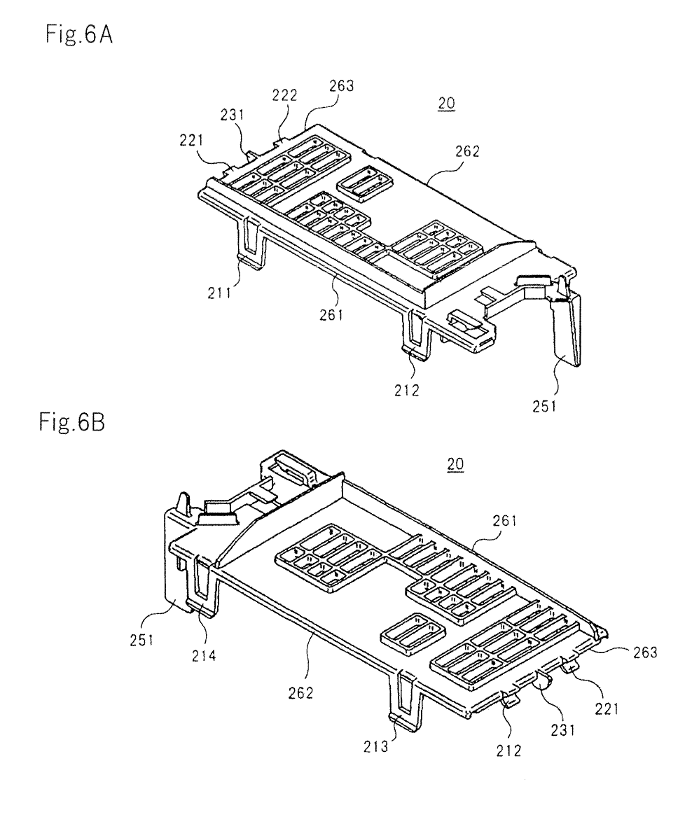

FIGS. 6A and 6B are perspective views showing lid 20 of the case for electronic components according to this embodiment. FIG. 6A shows the front side, and FIG. 6B shows the rear side.

Lid 20 includes locking pieces 211, 212, 213, and 214 that are second locking parts that form pairs with first locking parts 111, 112, 113, and 114 of container 10. Locking pieces 211 and 212 extend downward from one side edge 261 of lid 20, and locking pieces 213 and 214 extend downward from other side edge 262 of lid 20. Locking pieces 211, 212, 213, and 214 include openings formed in their centers.

At rear end 263 of lid 20, bearings 221 and 222 are formed corresponding to shafts 141 and 142 of container 10. Bearings 221 and 222 project rearward from rear end 263 to come into surface-contact with e circumferential surfaces of shafts 141 and 142.

At rear end 263, in a position between bearings 221 and 222, positioning piece 231,that is a second positioning part, is formed corresponding to notch 151 that is a first positioning part of container 10. Positioning piece 231 also projects rearward from rear end 263.

According to this embodiment, container 10 includes notch 151, and lid 20 includes positioning piece 231. However, a reverse configuration can he employed. Specifically, the container can include a positioning piece, and the lid can include a notch.

When lid 20 is mounted to container 10, positioning piece 231 of lid 20 is first inserted into notch 151 of container 10, and lid 20 is positioned relative to container 10.

Thus, notch 151 of container 10 defines the relative position of lid 20 to container 10 and, when lid 20 is mounted to container 10, positioning piece 231 is engaged with notch 151, thereby maintaining lid 20 and container 10 at correct relative positions. As a result, when lid 20 is mounted to container 10, shield 251 projecting downward is prevented from coming into contact with the electronic components or the like located on electronic substrate 30 in the container.

After lid 20 has been positioned relative to container 10 as described above, bearings 221 and 222 are brought into surface-contact with shafts 141 and 142, In this case, a state is as shown in FIGS. 2A and 2B.

Lid 20 is then rotated downward while the contact of bearings 221 and 222 with shafts 141 and 142 is maintained. In this case, bearings 221 and 222 slide along the circumferential surfaces of shafts 141 and 142. Thus, shafts 141 and 142 function as guides to guide bearings 221 and 222 that are guided parts when lid 20 rotates.

Shafts 141 and 142 define the rotational center of lid 20. Lid 20 accordingly rotates in a correct orbit with respect to container 10. This prevents shield 251 from coming into contact with the electronic components or the like arranged on electronic substrate 30 in the container when lid 20 is mounted to container 10.

According to this embodiment, container 10 includes shafts 141 and 142, and lid 20 includes bearings 221 and 222. However, a reverse configuration can be employed. Specifically, the container can include bearings, and the lid can include shafts. As in the abovementioned case, the shafts of the container function as guides to guide the shafts of the lid, and define the rotational center of the lid.

When lid 20 is rotated downward, the lower ends of locking pieces 211 and 213 reach positions on the upper ends of side walls 161 and 162, and locking pieces 211 and 213 then move downward along outer surfaces of side walls 161 and 162. When lid 20 is rotated further downwards, the lower ends of locking pieces 211 and 213 abut on locking parts 111 and 113 of container 10.

The lower ends of locking pieces 211 and 213 have shapes opened in the outward direction. Thus, locking pieces 211 and 213 receive outward forces from locking parts 111 and 113 to be elastically deformed, and placed on locking parts 111 and 113.

Locking pieces 211 and 213 receive locking parts 111 and 113 through their openings causing them to be engaged with locking parts 111 and 113. Similarly, locking pieces 212 and 214 receive locking parts 112 and 114 through their openings causing them to be engaged with locking parts 112 and 114.

In this case, the case for electronic components is in a closed state shown in FIGS. 3A and 3B. Locking pieces 211, 212, 213, and 214 are engaged with locking parts 111, 112, 113, and 114 from the lower side. Locking pieces 211, 212, 213, and 214 accordingly define the upward rotation of lid 20 with respect to container 10.

Locking pieces 211, 212, 213, and 214 are also engaged with locking parts 111, 112, 113, and 114 from the front side and the rear side. Locking pieces 211, 212, 213, and 214 accordingly define the back-and-forth motion of lid 20 with respect to container 10.

Thus, in the case for electronic components according to this embodiment, lid 20 is fixed to container 10 by engaging locking parts 111, 112 113 and 114 with locking pieces 211, 212, 213, and 214.

According to this embodiment, container 10 includes locking parts 111, 112, 113 and 114, and lid 20 includes locking pieces 211, 212, 213 and 214. However, a reverse configuration can be employed. Specifically, the container can include locking pieces, and the lid can include locking parts.

The case for electronic components according to this embodiment includes, in addition to locking pieces 211, 212, 213, and 214 and locking parts 111, 112, 113. and 114, a regulation mechanism for regulating motion of lid 20 with respect to container 10 in the closed state of lid 20.

Deformation parts 131, 132, 133, and 134 shown in FIG. 5A also function as regulation mechanisms. In the closed state of lid 20 shown in FIGS. 3A and 3B, in deformation part 131 shown in FIG. 5A, projection 131a is pressed to the inner surface of lid 20, and the part between projection 131a and slit 131b is elastically deformed so that it is caused to be distorted downwardly. Deformation parts 132, 133, and 134 are in the same state as that of deformation part 131.

Thus, when lid 20 is closed, the inner surface of lid 20 is pressed upward by the elastic force of deformation parts 131, 132, 133 and 134. As a result, abutment of locking parts 111, 112, 113 and 114 of container 10 on locking pieces 211, 212, 213 and 214 of lid 20 from the lower side is maintained, thereby preventing vertical backlash of lid 20 with respect to container 10.

Convex parts 121 and 122 described above also function as regulation mechanisms. In the closed state of lid 20 shown in FIGS. 3A and 3B, convex part 121 abuts on locking piece 211 from the front side, and convex part 122 abuts on locking piece 212 from the rear side. This prevents horizontal backlash of lid 20 with respect to container 10.

In other words, in the case for electronic components according to this embodiment, vertical and horizontal backlash of lid 20 with respect to container 10 is prevented, and shield 251 is prevented from coming into contact with the electronic components or the like located on electronic substrate 30 in the mounted state of lid 20 to container 10.

Next, the configuration of side edges 261 and 262 of lid 20 and their peripheral parts will be described.

Container 10 is made of a resin material such as plastic as in the case of lid 20. Side walls 161 and 162 of container 10 are accordingly deformed when they receive a side force.

In the closed state of lid 20, when side walls 161 and 162 of container 10 are deformed inside, locking parts 111, 112, 113 and 114 of container 10 are disengaged from locking pieces 211, 212, 213 and 214 of lid 20. Side edges 261 and 262 of lid 20 and their peripheral parts are configured to prevent such failures.

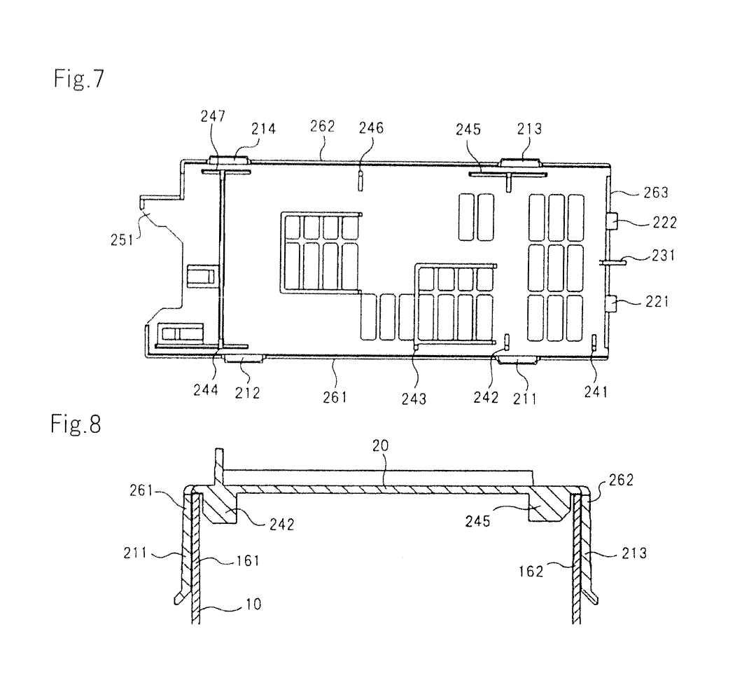

FIG. 7 shows the inner surface of lid 20. Specifically, FIG. 7 shows lid 20 shown in FIGS. 6A and 6B from the lower side.

Side edges 261 and 262 have parts projecting from the inner surface of lid 20 in addition to those including locking pieces 211, 212, 213 and 214 of lid 20. Little inside side edges 261 and 262 of lid 20, regulation parts 241 to 247 that project from the inner surface of lid 20 are formed.

FIG. 8 is a partial sectional view cut along line C-C′ shown in FIG. 3A. In the closed state of lid 20, side edge 261 and regulation part 244 sandwich the upper end of side wall 161 of container 10, and side edge 262 and regulation part 247 sandwich the upper end of side wall 162 of container 10.

Similarly, side edge 261 and regulation parts 241, 242, and 243 sandwich the upper end of side wall 161 of container 10, and side edge 262 and regulation parts 245 and 246 sandwich the upper end of side wall 162 of container 10.

In the closed state of lid 20, the upper ends of side walls 161 and 162 of container 10 are accordingly fixed to the side by lid 20. As a result, side walls 161 and 162 of container 10 are difficult to be deformed even when they receive a side force.

Thus, in the case for electronic components according to this embodiment, the engagement between locking parts 111, 112, 113 and 114 of container 10 and locking pieces 211, 212, 213 and 214 of lid 20 is maintained. As a result, lid 20 is kept fixed to container 10 without unintentionally opening lid 20 due to vibration or the like.

The embodiment of the present invention have been described. However, the present invention is not limited to this embodiment. Various changes understandable to those skilled in the art can be made of the configuration of the present invention without departing from the spirit and the scope of the invention.

### EXPLANATION OF REFERENCE NUMERALS

10 container

20 lid

30 electronic substrate

251 shield

1. A case for electronic components, comprising:
a container for housing a plurality of electronic components; and
an openable and closable lid mounted to the container,
wherein the lid includes a shield projecting from its inner surface and located between two electronic components when the lid is closed so that its leading end can abut on a mounting surface on which the two electronic components are mounted.

2. The case for electronic components according to claim 1, wherein:
the lid is rotatably mounted to the container;
the container includes a first positioning part to define a relative position of the lid to the container, and a guide to define a rotational center of the lid; and
the lid includes a second positioning part engaged with the first positioning part when the lid is mounted to the container, and a guided part slid along the guide when the lid rotates.

3. The case for electronic components according to claim 2, wherein:
the container includes a first locking part, and the lid includes a second locking part forming a pair with the first locking part; and
when the lid is closed, the first locking part and the second locking part are engaged with each other to fix the lid to the container.
